(19) United States
(12) Patent Application Publication
(10) Pub. No.: US 2026/0367743 A1
(43) Pub. Date: Nov. 19, 2026

(54) TOUCH DISPLAY PANEL AND TOUCH DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Yufeng LIU, Wuhan (CN); Chao DAI, Wuhan (CN); Yanqing GUAN, Wuhan (CN); Fu LI, Wuhan (CN); Liang MA, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 19/743,642

(22) Filed: Jul. 16, 2026

(30) Foreign Application Priority Data
Jan. 27, 2026 (CN) 202610114108.6

(51) Int. Cl. G06F 3/044; H10K 59/12; H10K 59/40

(52) U.S. Cl. CPC G06F 3/0446; G06F 3/0443; H10K 59/1201; H10K 59/40; G06F 2203/04103

(57) ABSTRACT

A touch display panel and a touch display device are provided. The touch display panel includes a thin-film transistor array substrate and a touch device. The thin-film transistor array substrate includes a source-drain layer. The touch device includes a first insulating layer, a first metal layer disposed on the first insulating layer, a second insulating layer disposed on the first insulating layer and the first metal layer, and a second metal layer disposed on the second insulating layer. The first insulating layer is an inorganic insulating layer, and the second insulating layer is an organic insulating layer. A peripheral region of the touch display panel is provided with a wire-switching hole. The wire-switching hole at least penetrates through the first insulating layer and the second insulating layer. The second metal layer is electrically connected to the source-drain layer through the wire-switching hole.

### CROSS-REFERENCE TO RELATED APPLICATION

This application claims priority to and the benefit of Chinese Patent Application No. 202610114108.6, filed on Jan. 27, 2026. The disclosure of which is incorporated herein by reference in its entirety.

### TECHNICAL FIELD

The present disclosure relates to the field of display technologies, and in particular, to a touch display panel and a touch display device.

### BACKGROUND

An organic light-emitting diode (OLED) touch display panel generally includes a touch device. The touch device generally adopts a double-layer touch metal structure, which sequentially includes a first insulating layer, a first metal layer, a second insulating layer, and a second metal layer.

In the prior art, both the first insulating layer and the second insulating layer of the touch device are made of silicon nitride. Since a tensile elongation at break of the silicon nitride material is relatively low, in a case where the touch display panel is impacted or bent, the silicon nitride material is easy to break, resulting in failure of the touch display panel. As a result, the touch display panel has poor impact resistance and poor bending performance.

Therefore, it is necessary to propose a new technical solution to solve the above-described technical problems.

### SUMMARY

In a first aspect, the present disclosure provides a touch display panel, including a thin-film transistor array substrate and a touch device. The thin-film transistor array substrate includes a source-drain layer. The touch device includes a first insulating layer, a first metal layer, a second insulating layer, and a second metal layer. The first insulating layer is an inorganic insulating layer. The first metal layer is disposed on the first insulating layer. The second insulating layer is disposed on the first insulating layer and the first metal layer. The second insulating layer is an organic insulating layer. The second metal layer is disposed on the second insulating layer. The touch display panel includes a display region and a peripheral region located on at least one side of the display region. The peripheral region is provided with a wire-switching hole. The wire-switching hole at least penetrates through the first insulating layer and the second insulating layer. The second metal layer is electrically connected to the source-drain layer through the wire-switching hole.

In a second aspect, the present disclosure further provides a touch display device, including the above-described touch display panel and a driving chip. The driving chip is electrically connected to the touch display panel.

### BRIEF DESCRIPTION OF THE DRAWINGS

FIG. 1 is a schematic view of a touch display device according to one or more embodiments of the present disclosure.

FIG. 2 is a schematic view of a cross-sectional structure of a touch display panel at a wire-switching hole according to a first embodiment of the present disclosure.

FIG. 3 is a schematic view of a cross-sectional structure of a touch display panel at a wire-switching hole according to a second embodiment of the present disclosure.

FIGS. 4 to 10 are schematic views of processes for manufacturing a touch display panel according to one or more embodiments of the present disclosure.

### DETAILED DESCRIPTION

Specific embodiments of the present disclosure are described in detail below with reference to the accompanying drawings.

The terms “first,” “second,” and similar words do not indicate any order, quantity, or importance, but are only used to distinguish different technical features. A term “plurality” and similar words mean two or more than two, unless expressly limited otherwise.

Technical solutions of different embodiments of the present disclosure may be combined with each other.

The touch display device provided by the embodiments of the present disclosure is, for example, an OLED touch display device, a Mini-LED touch display device, or a Micro-LED touch display device. The embodiments of the present disclosure are described by taking the OLED touch display device as an example.

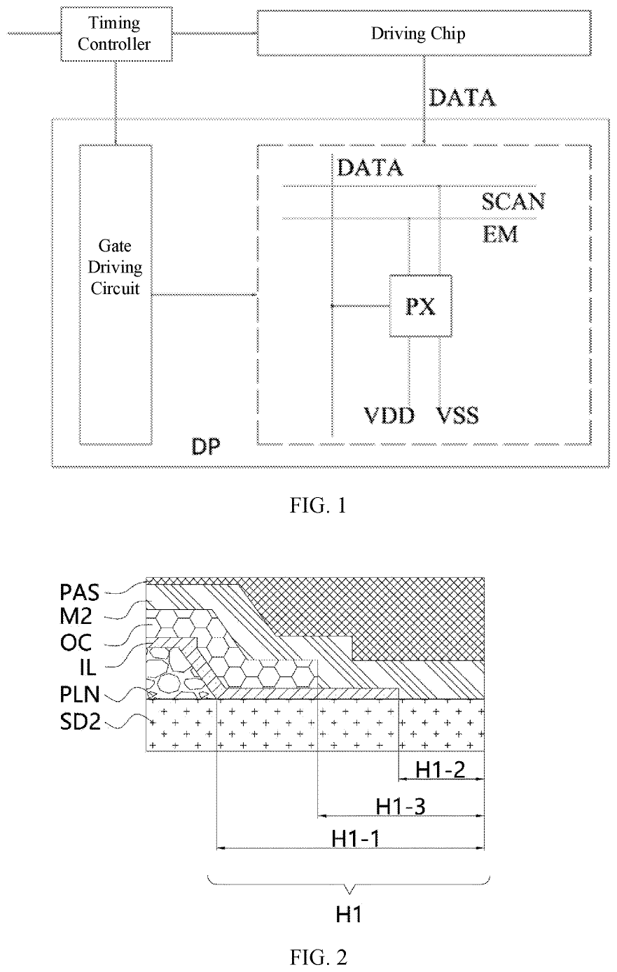

The embodiments of the present disclosure provide a touch display panel and a touch display device. As shown in FIG. 1, the touch display device includes a touch display panel DP and a driving chip. The touch display panel DP is, for example, an organic light-emitting diode display panel. The touch display panel DP includes a display region AA and a peripheral region PA located on at least one side of the display region AA.

As shown in FIG. 1, the touch display device further includes a timing controller. The timing controller is electrically connected to the driving chip. The driving chip is electrically connected to the touch display panel DP. The touch display panel DP includes a gate driving circuit, a plurality of gate lines SCAN, a plurality of light-emitting control signal lines EM, a plurality of first power lines VDD, a plurality of second power lines VSS, a plurality of data lines DATA, and a plurality of pixel units PX. The gate driving circuit is disposed in the peripheral region PA. The plurality of gate lines SCAN extend along a first direction. The plurality of data lines DATA extend along a second direction. The first direction is perpendicular to the second direction. The plurality of gate lines SCAN intersect the plurality of data lines DATA. The gate driving circuit is electrically connected to the plurality of gate lines SCAN. The gate driving circuit provides gate signals to the plurality of gate lines SCAN. The driving chip is electrically connected to the plurality of data lines DATA. The driving chip provides data signals to the plurality of data lines DATA. The plurality of light-emitting control signal lines EM are electrically connected to the gate driving circuit. The gate driving circuit provides light-emitting control signals to the plurality of light-emitting control signal lines EM. The timing controller provides control signals and image data to the gate driving circuit and the driving chip. Each pixel unit PX includes a plurality of thin film transistors and light-emitting devices. The thin film transistors are configured to control light emission of the light-emitting devices.

The touch display panel DP provided by the embodiments of the present disclosure includes a thin-film transistor array substrate, a light-emitting device layer, an encapsulation layer TFE, and a touch device. The light-emitting device layer is disposed on the thin-film transistor array substrate. The encapsulation layer TFE is disposed on the light-emitting device layer. The touch device is disposed on the encapsulation layer TFE.

The thin-film transistor array substrate includes a plurality of thin film transistors. Each thin film transistor includes a gate, a source, and a drain. The source and the drain are located in the source-drain layer. The source-drain layer includes a first source-drain layer SD1 and a second source-drain layer SD2. The second source-drain layer SD2 is disposed on the first source-drain layer SD1. The second source-drain layer SD2 is electrically connected to the first source-drain layer SD1. The thin-film transistor array substrate further includes a planarization layer PLN. The planarization layer PLN is disposed on the second source-drain layer SD2. A material of the planarization layer PLN is an organic material. The planarization layer PLN is configured to planarize a surface of the thin-film transistor array substrate.

The touch device includes a first insulating layer IL, a first metal layer M1, a second insulating layer OC, and a second metal layer M2. In the display region AA, the first insulating layer IL is disposed on the encapsulation layer TFE. In the peripheral region PA, the first insulating layer IL is disposed on the planarization layer PLN. The first metal layer M1 is disposed on the first insulating layer IL. The second insulating layer OC is disposed on the first insulating layer IL and the first metal layer M1. The second metal layer M2 is disposed on the second insulating layer OC. The touch display panel further includes a passivation layer PAS. The passivation layer PAS is disposed on the second metal layer M2.

The first insulating layer IL is an inorganic insulating layer. The first insulating layer IL includes silicon nitride. A material of the first insulating layer IL has hard and brittle properties, and has a low tensile elongation at break. In the display region AA, the first insulating layer IL covers the encapsulation layer TFE and is in direct contact with the encapsulation layer TFE. In the peripheral region PA, the first insulating layer IL covers the planarization layer PLN and is in direct contact with the planarization layer PLN.

The second insulating layer OC is an organic insulating layer. The second insulating layer OC is a low-temperature organic cover layer. A tensile elongation at break of the second insulating layer OC is greater than the tensile elongation at break of the first insulating layer IL. The second insulating layer OC is softer than the first insulating layer IL. The second insulating layer OC covers the first insulating layer IL and the first metal layer M1. In the display region AA and the peripheral region PA, the second insulating layer OC is disposed on the first insulating layer IL.

The first metal layer M1 includes first touch electrodes and second touch electrodes. The first touch electrodes extend along the first direction. The second touch electrodes extend along the second direction. The first direction is perpendicular to the second direction. The first touch electrodes and the second touch electrodes are both located on the first insulating layer IL. The first touch electrodes and the second touch electrodes are both located in the display region AA. A material of the first metal layer M1 includes at least one of molybdenum, aluminum, copper, or titanium.

The second metal layer M2 includes bridging lines. The bridging lines are disposed in the display region AA. In the display region AA, the second insulating layer OC is provided with at least one through hole H2 penetrating through the second insulating layer OC. The bridging line is electrically connected to the first touch electrode through the through hole H2. The bridging line fills the through hole H2 and is in contact with the first touch electrode exposed at a bottom of the through hole H2. The bridging line is configured to electrically connect two adjacent first touch electrodes. Two adjacent second touch electrodes are directly electrically connected with each other, and do not need to be bridged through the bridging line in the second metal layer M2. A material of the second metal layer M2 includes at least one of molybdenum, aluminum, copper, or titanium. A thickness of the second metal layer M2 is greater than a thickness of the first metal layer M1.

A material of the passivation layer PAS is an organic material. The passivation layer PAS covers the second metal layer M2. The passivation layer PAS is configured to protect the touch device.

The touch display panel DP further includes a light-shielding member BM and a color filter layer CF. The light-shielding member BM is disposed on the second metal layer M2 and the second insulating layer OC in the display region AA. In the display region AA, the light-shielding member BM is located on and covers the second metal layer M2. The color filter layer CF is disposed on the light-shielding member BM and the second insulating layer OC. The color filter layer CF includes red color filters R, green color filters G, and blue color filters B. The red color filters R, the green color filters G, and the blue color filters B are configured to achieve a polarization function. In the display region AA, the passivation layer PAS is disposed on the light-shielding member BM and the color filter layer CF. The passivation layer PAS covers the light-shielding member BM and the color filter layer CF.

The touch display panel DP is provided with a wire-switching hole H1 in the peripheral region PA. The wire-switching hole H1 is located outside the encapsulation layer TFE. The wire-switching hole H1 is located near a junction of the peripheral region PA and the display region AA, or the wire-switching hole H1 is located at a position of the peripheral region PA away from the display region AA. The wire-switching hole H1 at least penetrates through the first insulating layer IL and the second insulating layer OC. The wire-switching hole H1 further penetrates through the planarization layer PLN. The second source-drain layer SD2 is further disposed in a portion of the thin-film transistor array substrate located in the peripheral region PA. The second metal layer M2 is electrically connected to the second source-drain layer SD2 through the wire-switching hole H1. The wire-switching hole H1 includes a first opening H1-1 penetrating through the planarization layer PLN. The first opening H1-1 penetrates from a top surface of the planarization layer PLN to a bottom surface of the planarization layer PLN. The first opening H1-1 exposes a portion of the second source-drain layer SD2 located in the peripheral region PA. In the peripheral region PA, a portion of the first insulating layer IL is disposed on the second source-drain layer SD2 and located within the first opening H1-1. This portion of the first insulating layer IL is in direct contact with the second source-drain layer SD2. At least a portion of the second insulating layer OC is disposed on the portion of the first insulating layer IL located within the first opening H1-1. This portion of the second insulating layer OC is in direct contact with the portion of the first insulating layer IL within the first opening H1-1.

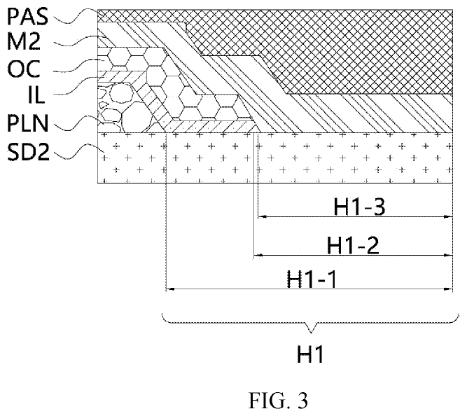

As shown in FIGS. 2 and 3, the wire-switching hole H1 further includes a second opening H1-2 penetrating through the first insulating layer IL and a third opening H1-3 penetrating through the second insulating layer OC. The second opening H1-2 penetrates from a top surface of the first insulating layer IL to a bottom surface of the first insulating layer IL. The third opening H1-3 penetrates from a top surface of the second insulating layer OC to a bottom surface of the second insulating layer OC. In a top view of the touch display panel DP, a diameter of a minimum circumscribed circle of the second opening H1-2 and a diameter of a minimum circumscribed circle of the third opening H1-3 are both smaller than a diameter of a minimum circumscribed circle of the first opening H1-1. In the top view of the touch display panel DP, the diameter of the minimum circumscribed circle of the second opening H1-2 is smaller than the diameter of the minimum circumscribed circle of the third opening H1-3. A step portion is formed by the first insulating layer IL and the second insulating layer OC at the wire-switching hole H1. The step portion is formed by an edge of the first insulating layer IL at the wire-switching hole H1 and an edge of the second insulating layer OC at the wire-switching hole H1. The step portion includes a sidewall of the first insulating layer IL and a sidewall of the second insulating layer OC. The sidewall of the first insulating layer IL corresponds to an edge of the second opening H1-2. The sidewall of the second insulating layer OC corresponds to an edge of the third opening H1-3. The edge of the first insulating layer IL at the wire-switching hole H1 is located below the edge of the second insulating layer OC at the wire-switching hole H1. The second metal layer M2 extends across the step portion to a bottom of the wire-switching hole H1. The second metal layer M2 is electrically connected to the second source-drain layer SD2 at the bottom of the wire-switching hole H1. A portion of the second metal layer M2 is disposed on the second insulating layer OC, and this portion is located outside the wire-switching hole H1 and in direct contact with the top surface of the second insulating layer OC. Another portion of the second metal layer M2 is disposed on the step portion, this portion covers the step portion and is in direct contact with the step portion, and this portion extends along a contour of the step portion. Another portion of the second metal layer M2 is disposed on the edge of the first insulating layer IL at the wire-switching hole H1, and this portion covers the sidewall of the first insulating layer IL and is in direct contact with the sidewall of the first insulating layer IL. Another portion of the second metal layer M2 is disposed on the second source-drain layer SD2 and electrically connected to the second source-drain layer SD2. This portion is located at the bottom of the wire-switching hole H1 and in direct contact with the portion of the second source-drain layer SD2 located within the first opening H1-1. From the top surface of the second insulating layer OC, the second metal layer M2 sequentially crosses the sidewall of the second insulating layer OC and the sidewall of the first insulating layer IL, and finally reaches the bottom of the wire-switching hole H1 and is electrically connected to the second source-drain layer SD2.

In another embodiment, the sidewall of the first insulating layer IL at the wire-switching hole H1 is aligned with the sidewall of the second insulating layer OC at the wire-switching hole H1. In this embodiment, when the first insulating layer IL is etched, the second insulating layer OC acts as an etching barrier layer or a hard mask. Since the second insulating layer OC covers the first insulating layer IL and the dry etching process is anisotropic etching, the etching gas reaches the first insulating layer IL through the third opening H1-3 and etches the first insulating layer IL. A size of an opening of the first insulating layer IL is limited by a size of an opening of the second insulating layer OC to form a self-alignment structure. In the top view of the touch display panel DP, the diameter of the minimum circumscribed circle of the second opening H1-2 is substantially equal to the diameter of the minimum circumscribed circle of the third opening H1-3, or the diameter of the minimum circumscribed circle of the second opening H1-2 is slightly smaller than the diameter of the minimum circumscribed circle of the third opening H1-3. The sidewall of the first insulating layer IL and the sidewall of the second insulating layer OC are aligned or substantially aligned in a vertical direction or an inclined direction to jointly form a hole wall. The inclined direction refers to a direction where the included angle with the vertical direction is less than 90 degrees. The “substantially aligned” refers to a distance between a plane where the sidewall of the first insulating layer IL is located and a plane where the sidewall of the second insulating layer OC is located being greater than 0 nm and less than 500 nm. The hole wall includes an inclined surface portion. An included angle formed between the inclined surface portion and the horizontal plane ranges from 30 degrees to 80 degrees. The second metal layer M2 extends from the top surface of the second insulating layer OC to the bottom of the wire-switching hole H1 along the hole wall and is electrically connected to the second source-drain layer SD2. The second metal layer M2 covers the inclined surface portion. A portion of the second metal layer M2 is disposed on the top surface of the second insulating layer OC, and this portion is located outside the wire-switching hole H1 and in direct contact with the top surface of the second insulating layer OC. Another portion of the second metal layer M2 is disposed on the hole wall, and this portion covers the sidewall of the second insulating layer OC and the sidewall of the first insulating layer IL and extends along a contour of the hole wall. Another portion of the second metal layer M2 is disposed on the second source-drain layer SD2 and electrically connected to the second source-drain layer SD2, and this portion is located at the bottom of the wire-switching hole H1 and in direct contact with this portion of the second source-drain layer SD2 located within the first opening H1-1. From the top surface of the second insulating layer OC, the second metal layer M2 extends downward along the continuous hole wall formed by the sidewall of the first insulating layer IL and the sidewall of the second insulating layer OC, and finally reaches the bottom of the wire-switching hole H1 and is electrically connected to the second source-drain layer SD2.

The source-drain layer includes a first portion located in the display region AA and a second portion located in the peripheral region PA. A thickness of the first portion is equal to a thickness of the second portion. The first portion includes the second source-drain layer SD2 located in the display region AA. The second portion includes the second source-drain layer SD2 located in the peripheral region PA. The second source-drain layer SD2 located in the display region AA and the second source-drain layer SD2 located in the peripheral region PA are formed in a same processing step, so the thicknesses of the two are the same.

The peripheral region PA is further provided with a solder pad. The solder pad is located in a bonding region BA of the peripheral region PA. The solder pad includes a first metal pad located in the first source-drain layer SD1 and a second metal pad located in the second source-drain layer SD2. The second metal pad is disposed on the first metal pad. The second metal pad is in direct contact with and electrically connected to the first metal pad. The first insulating layer IL on the second metal pad at the solder pad is removed, and the second metal pad is exposed. A top surface of the second metal pad is exposed, and the driving chip is in contact with a top surface of the second metal pad. The driving chip is electrically connected to the touch display panel DP through the solder pad in the peripheral region PA.

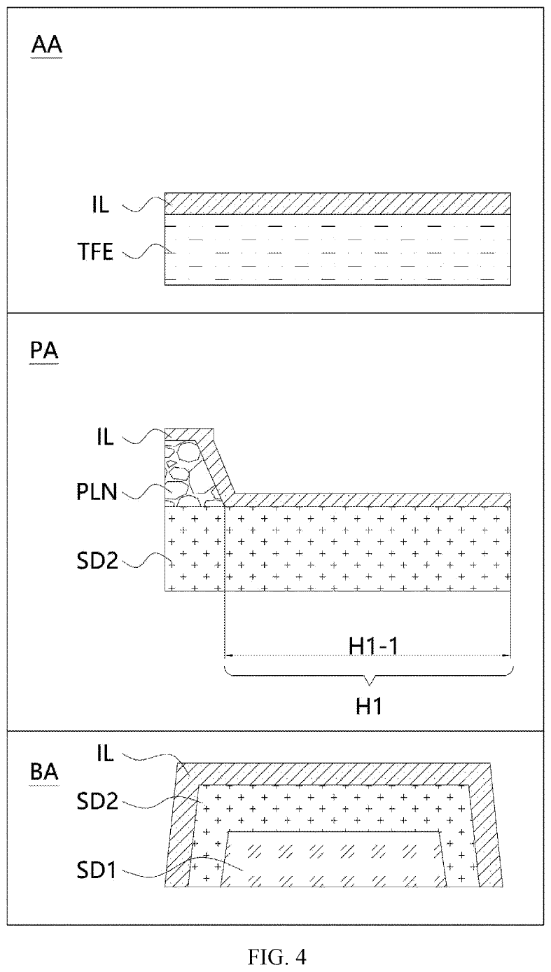

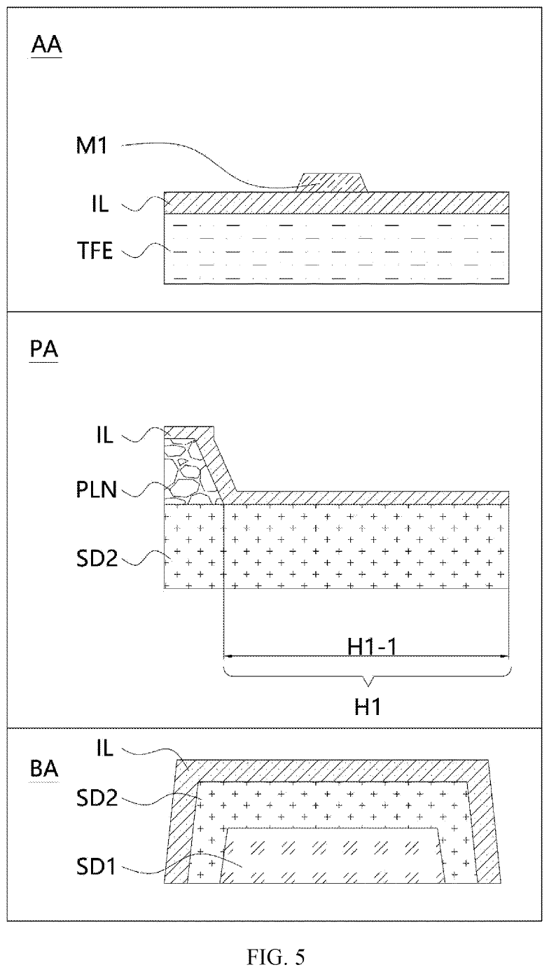

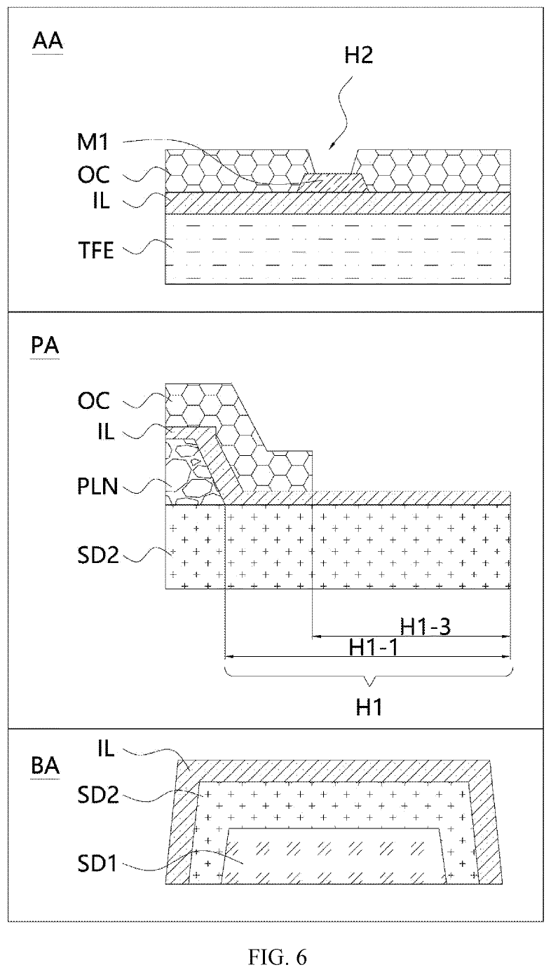

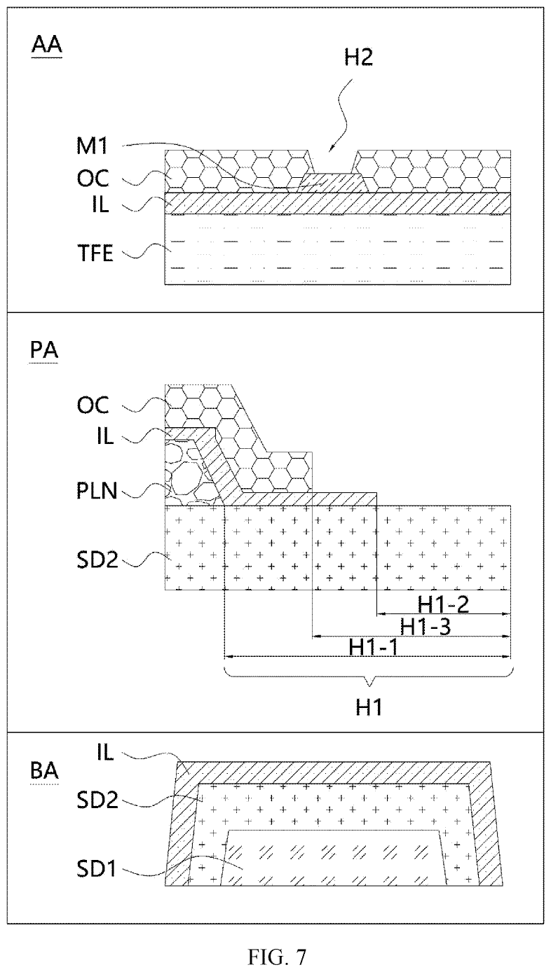

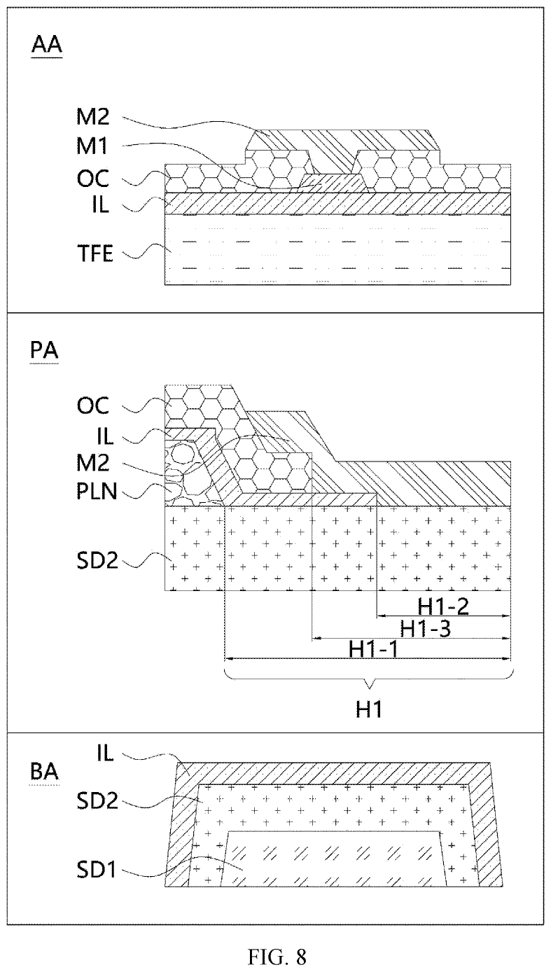

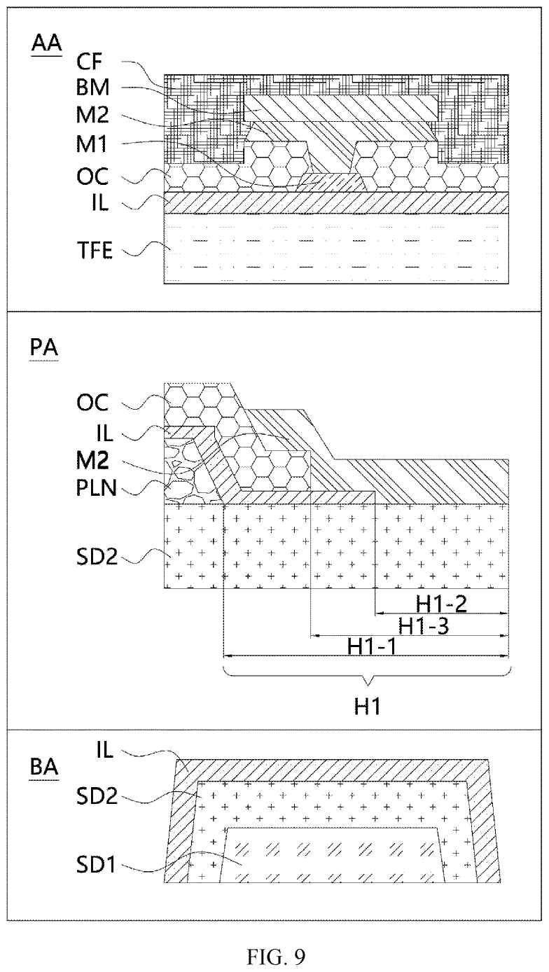

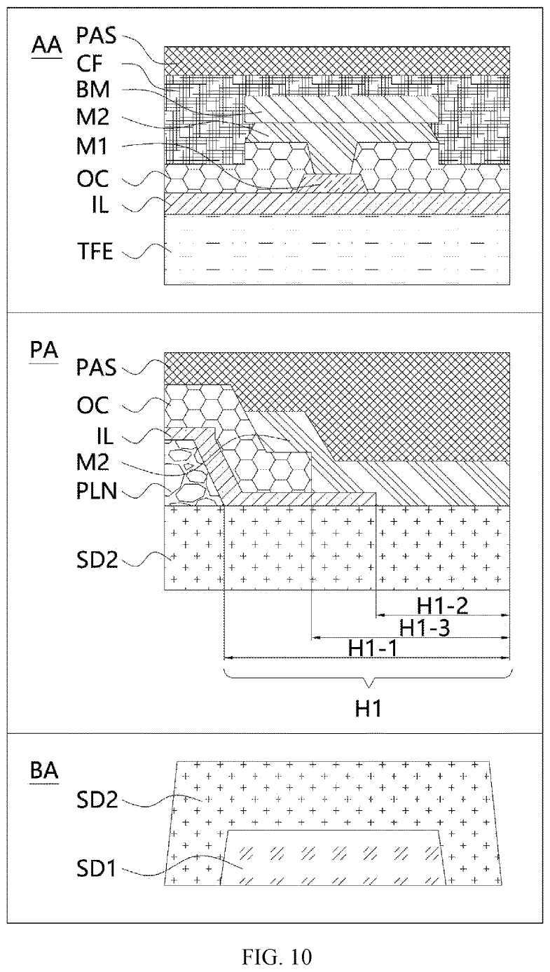

The embodiments of the present disclosure further provide a manufacturing method of a touch display panel DP. As shown in FIGS. 4 to 10, the manufacturing method includes following steps.

A thin-film transistor array substrate is manufactured. The thin-film transistor array substrate includes a first source-drain layer SD1 and a second source-drain layer SD2. The second source-drain layer SD2 is disposed on and electrically connected to the first source-drain layer SD1. The thin-film transistor array substrate further includes a planarization layer PLN. The planarization layer PLN is disposed on the second source-drain layer SD2. At a wire-switching hole H1 in a peripheral region PA, the planarization layer PLN is etched to form a first opening H1-1 in the planarization layer PLN. The first opening H1-1 penetrates through the planarization layer PLN and exposes the second source-drain layer SD2. An etching process of the planarization layer PLN includes coating photoresist on the planarization layer PLN, exposing and developing the photoresist, etching the planarization layer PLN by the etching process, and removing the photoresist.

forming a light-emitting device layer on the thin-film transistor array substrate. An encapsulation layer TFE is formed on the light-emitting device layer. The encapsulation layer TFE covers the light-emitting device layer. In a display region AA, the encapsulation layer TFE covers the light-emitting device layer. In the peripheral region PA, the encapsulation layer TFE does not extend to the wire-switching hole H1.

A first insulating layer IL is formed on the encapsulation layer TFE. The first insulating layer IL is formed by a chemical vapor deposition process. The first insulating layer IL covers the encapsulation layer TFE. In the peripheral region PA, the first insulating layer IL covers the planarization layer PLN and the second source-drain layer SD2. At the wire-switching hole H1 in the peripheral region PA, a portion of the first insulating layer IL is disposed on the second source-drain layer SD2 within the first opening H1-1. This portion of the first insulating layer IL fills the first opening H1-1 or partially fills the first opening H1-1. At a solder pad in the peripheral region PA, the first insulating layer IL covers a second metal pad. The first insulating layer IL formed by the chemical vapor deposition process forms a uniform film layer covering a surface of the substrate.

A first metal layer M1 is formed on the first insulating layer IL. The first metal layer M1 is deposited on the first insulating layer IL by a sputtering process. A metal material is deposited on a surface of the first insulating layer IL by the sputtering process. A photolithography process is performed on the first metal layer M1, a photoresist is coated on the first metal layer M1, and the photoresist is exposed and developed. A dry etching process is performed on the first metal layer M1 to form first touch electrodes and second touch electrodes. The dry etching process removes a portion of the first metal layer M1 not protected by the photoresist, and retains a portion of the first metal layer M1 protected by the photoresist. The photoresist is removed from the first metal layer M1 after the photolithography process by a photoresist removal process. The photoresist remaining on the first touch electrode and the second touch electrode is removed by the photoresist removal process.

A second insulating layer OC is formed on the first insulating layer IL and the first metal layer M1. The second insulating layer OC is formed on the first insulating layer IL and the first metal layer M1 by a spin coating process. An organic material solution is coated on the substrate by a spin coating process, and the organic material solution is uniformly distributed by rotating the substrate to form the second insulating layer OC. A photolithography process is performed on the second insulating layer OC to form a through hole H2 in the second insulating layer OC. The through hole H2 penetrates through the second insulating layer OC and exposes the first metal layer M1. The photolithography process includes coating photoresist on the second insulating layer OC, exposing and developing the photoresist, and removing the exposed portion of the second insulating layer OC to form the through hole H2. After the photolithography process is completed, the second insulating layer OC is baked. The second insulating layer OC is cured by a baking treatment. In the display region AA, the through hole H2 exposes the first touch electrode. At the wire-switching hole H1 in the peripheral region PA, the second insulating layer OC forms a third opening H1-3. The third opening H1-3 penetrates through the second insulating layer OC. At the wire-switching hole H1 in the peripheral region PA, at least a portion of the second insulating layer OC is disposed on the portion of the first insulating layer IL located within the first opening H1-1. An edge portion of the second insulating layer OC at the wire-switching hole H1 covers an edge portion of the first insulating layer IL at the wire-switching hole H1.

The first insulating layer IL is etched. The step of etching the first insulating layer IL is performed after the step of forming the second insulating layer OC. The step of etching the first insulating layer IL includes: coating photoresist on the second insulating layer OC, exposing and developing the photoresist, etching the first insulating layer IL by a dry etching process, forming a second opening H1-2 in the first insulating layer IL, and removing the photoresist. At the wire-switching hole H1 in the peripheral region PA, the first insulating layer IL forms a second opening H1-2. The second opening H1-2 formed by the first insulating layer IL at the wire-switching hole H1 exposes the second source-drain layer SD2. The dry etching process etches the first insulating layer IL in the vertical direction to remove the portion of the first insulating layer IL located within the first opening H1-1.

A diameter of a minimum circumscribed circle of the second opening H1-2 is smaller than a diameter of a minimum circumscribed circle of the third opening H1-3, or the diameter of the minimum circumscribed circle of the second opening H1-2 is substantially equal to the diameter of the minimum circumscribed circle of the third opening H1-3. In a case where the diameter of the minimum circumscribed circle of the second opening H1-2 is smaller than the diameter of the minimum circumscribed circle of the third opening H1-3, a step portion is formed by the first insulating layer IL and the second insulating layer OC at the wire-switching hole H1. The step portion is formed by an edge of the first insulating layer IL at the wire-switching hole H1 and an edge of the second insulating layer OC at the wire-switching hole H1. The edge of the first insulating layer IL at the wire-switching hole H1 is located on a side of the third opening H1-3 close to a center of the wire-switching hole H1. A sidewall of the first insulating layer IL corresponds to an edge of the second opening H1-2. A sidewall of the second insulating layer OC corresponds to an edge of the third opening H1-3. In a case where the diameter of the minimum circumscribed circle of the second opening H1-2 is substantially equal to the diameter of the minimum circumscribed circle of the third opening H1-3, the second insulating layer OC acts as an etching barrier layer or a hard mask. The sidewall of the first insulating layer IL and the sidewall of the second insulating layer OC are aligned or substantially aligned in a vertical direction or an inclined direction to joint form the hole wall. The hole wall includes an inclined surface portion, and an included angle formed between the inclined surface portion and the horizontal plane ranges from 30 degrees to 80 degrees.

A second metal layer M2 is formed on the second insulating layer OC. The second metal layer M2 is deposited on the second insulating layer OC by a sputtering process. A metal material is deposited on the surface of the second insulating layer OC by the sputtering process. The metal material covers the top surface of the second insulating layer OC, the sidewall of the through hole H2, and the step portion at the wire-switching hole H1. In the display region AA, the second metal layer M2 fills the through hole H2 in the second insulating layer OC. The second metal layer M2 is electrically connected to the first metal layer M1 through the through hole H2. The second metal layer M2 is in contact with and electrically connected to the first touch electrode at a bottom of the through hole H2. At the wire-switching hole H1 in the peripheral region PA, the second metal layer M2 extends to the bottom of the wire-switching hole H1 and is electrically connected to the second source-drain layer SD2. In the case where the diameter of the minimum circumscribed circle of the second opening H1-2 is smaller than the diameter of the minimum circumscribed circle of the third opening H1-3, the second metal layer M2 extends across the step portion to the bottom of the wire-switching hole H1. The second metal layer M2 extends along a contour of the step portion. From the top surface of the second insulating layer OC, the second metal layer M2 sequentially covers the sidewall of the second insulating layer OC and the sidewall of the first insulating layer IL, and finally reaches the bottom of the wire-switching hole H1. In the case where the diameter of the minimum circumscribed circle of the second opening H1-2 is substantially equal to the diameter of the minimum circumscribed circle of the third opening H1-3, the second metal layer M2 extends along the hole wall to the bottom of the wire-switching hole H1. From the top surface of the second insulating layer OC, the second metal layer M2 extends downward along the continuous hole wall formed by the sidewall of the first insulating layer IL and the sidewall of the second insulating layer OC, covers the inclined surface portion of the hole wall, and finally reaches the bottom of the wire-switching hole H1 and is electrically connected to the second source-drain layer SD2. A photolithography process is performed on the second metal layer M2, photoresist is coated on the second metal layer M2, and the photoresist is exposed and developed. A dry etching process is performed on the second metal layer M2 to form a bridging line. The dry etching process removes the portion of the second metal layer M2 not protected by the photoresist, and retains the portion of the second metal layer M2 protected by the photoresist to form the bridging line. The photoresist is removed from the second metal layer M2 after the photolithography process by a photoresist removal process.

A light-shielding member BM is formed on the second insulating layer OC and the second metal layer M2 in the display region AA. The light-shielding member BM is formed by a photolithography process. The photolithography process includes coating a light-shielding material, exposing and developing the light-shielding material, and removing the unexposed light-shielding material. A color filter layer CF is formed on the light-shielding member BM. The color filter layer CF includes red color filters R, green color filters G, and blue color filters B. The color filter layer CF is formed by a photolithography process. The photolithography process includes sequentially coating a red color filter material, a green color filter material and a blue color filter material, and exposing and developing the red color filter material, the green color filter material, and the blue color filter material respectively to form the red color filters R, the green color filters G, and the blue color filters B. A baking treatment is performed on the color filter layer CF. The color filter layer CF is cured by the baking treatment.

A passivation layer PAS is formed on the second metal layer M2. In the display region AA, the passivation layer PAS is formed on the light-shielding member BM and the color filter layer CF. The passivation layer PAS is formed by a spin coating process or a printing process. An organic material is coated on the light-shielding member BM and the color filter layer CF by the spin coating process or the printing process to form the passivation layer PAS. A photolithography process is performed on the passivation layer PAS. The photolithography process includes coating a photoresist on the passivation layer PAS, and exposing and developing the photoresist. A baking treatment is performed on the passivation layer PAS. The passivation layer PAS is cured by the baking treatment. An ashing treatment and a dry etching process are performed on the passivation layer PAS. Residual organic matter is removed by an ashing treatment, and the passivation layer PAS is etched by a dry etching process. At the solder pad in the peripheral region PA, the first insulating layer IL on the solder pad is removed by a dry etching process to expose the second metal pad. The first insulating layer IL covering the second metal pad is removed by the dry etching process, so that a top surface of the second metal pad is exposed.

In the touch display panel DP provided by the embodiments of the present disclosure, the organic insulating layer is used as the second insulating layer OC in the touch device to replace the inorganic silicon nitride material in the prior art, thereby improving the impact resistance and bending performance of the touch display panel DP. The tensile elongation at break of the second insulating layer OC is greater than the tensile elongation at break of the first insulating layer IL. In a case where the touch display panel DP is impacted or bent, the second insulating layer OC is not easy to break, thereby avoiding failure of the touch display panel DP and improving the reliability of the touch display panel DP.

The touch display panel DP of the present disclosure is provided with the wire-switching hole H1 in the peripheral region PA. The wire-switching hole H1 at least penetrates through the first insulating layer IL and the second insulating layer OC. The second metal layer M2 is electrically connected to the second source-drain layer SD2 through the wire-switching hole H1. The second metal layer M2 is electrically connected to the second source-drain layer SD2 to realize wire switching of the touch electrodes. Since the thickness of the second metal layer M2 is greater than the thickness of the first metal layer M1, a resistivity of the second metal layer M2 is less than a resistivity of the first metal layer M1, and a contact resistance between the second metal layer M2 and the second source-drain layer SD2 is less than a contact resistance between the first metal layer M1 and the second source-drain layer SD2, thereby reducing the impedance of the wiring of the touch electrodes and improving the touch performance of the touch display panel DP.

In the touch display panel DP of the present disclosure, the second insulating layer OC is an organic insulating layer. The first insulating layer IL and the second insulating layer OC respectively form the second opening H1-2 and the third opening H1-3 at the wire-switching hole H1. The step portion formed by the second metal layer M2 across the first insulating layer IL and the second insulating layer OC at the wire-switching hole H1 is electrically connected to the second source-drain layer SD2. The covering performance of the second metal layer M2 on the step portion at the wire-switching hole H1 is good, and the reliability of the electrical connection between the second metal layer M2 and the second source-drain layer SD2 is high, thereby improving the reliability of the touch display panel DP.

In the manufacturing method of the touch display panel DP of the present disclosure, the etching step of the first insulating layer IL is performed after the step of forming the second insulating layer OC. Compared with a solution in which the first insulating layer IL is etched before the second insulating layer OC is formed in the prior art, in the manufacturing method of the present disclosure, a wire switching manner in which the second metal layer M2 is electrically connected to the second source-drain layer SD2 is maintained, and the wire switching manner in which the first metal layer M1 is electrically connected to the second source-drain layer SD2 is avoided. Since the thickness of the first metal layer M1 is less than the thickness of the second metal layer M2, the wire switching manner in which the first metal layer M1 is electrically connected to the second source-drain layer SD2 will cause the impedance at the wire-switching hole H1 to increase, which affects the performance of the touch display panel DP. In the manufacturing method of the present disclosure, the etching step of the first insulating layer IL is followed, and while the second insulating layer OC is maintained as the organic insulating layer to improve the bending performance, the wire switching mode in which the second metal layer M2 is electrically connected to the second source-drain layer SD2 is maintained, the impedance at the wire-switching hole H1 is reduced, and the performance of the touch display panel DP is improved.

The embodiments of the present disclosure have been described in detail above, and the contents of this specification should not be construed as limiting the scope of protection of the present disclosure.

What is claimed is:

1. A touch display panel, comprising:
a thin-film transistor array substrate comprising a source-drain layer; and
a touch device comprising:
a first insulating layer, wherein the first insulating layer is an inorganic insulating layer;
a first metal layer disposed on the first insulating layer;
a second insulating layer disposed on the first insulating layer and the first metal layer, wherein the second insulating layer is an organic insulating layer; and
a second metal layer disposed on the second insulating layer;
wherein the touch display panel comprises a display region and a peripheral region located on at least one side of the display region, the peripheral region is provided with a wire-switching hole, the wire-switching hole at least penetrates through the first insulating layer and the second insulating layer, and the second metal layer is electrically connected to the source-drain layer through the wire-switching hole.

2. The touch display panel according to claim 1, wherein the thin-film transistor array substrate further comprises a planarization layer disposed on the source-drain layer, and the wire-switching hole comprises a first opening penetrating through the planarization layer; and
wherein in the peripheral region, the first insulating layer is disposed on the planarization layer, a portion of the first insulating layer is disposed on the source-drain layer and located within the first opening, and at least a portion of the second insulating layer is disposed on the portion of the first insulating layer located within the first opening.

3. The touch display panel according to claim 2, wherein the wire-switching hole further comprises a second opening penetrating through the first insulating layer and a third opening penetrating through the second insulating layer; and
wherein in a top view of the touch display panel, a diameter of a minimum circumscribed circle of the second opening and a diameter of a minimum circumscribed circle of the third opening are both smaller than a diameter of a minimum circumscribed circle of the first opening.

4. The touch display panel according to claim 3, wherein in the top view of the touch display panel, the diameter of the minimum circumscribed circle of the second opening is smaller than the diameter of the minimum circumscribed circle of the third opening.

5. The touch display panel according to claim 4, wherein a step portion is formed by an edge of the first insulating layer at the wire-switching hole and an edge of the second insulating layer at the wire-switching hole, and the second metal layer crosses through the step portion and is electrically connected to the source-drain layer.

6. The touch display panel according to claim 3, wherein at the wire-switching hole, a sidewall of the first insulating layer is aligned with a sidewall of the second insulating layer; and wherein along a hole wall formed by the sidewall of the first insulating layer and the sidewall of the second insulating layer, the second metal layer extends from a top surface of the second insulating layer to a bottom of the wire-switching hole and is electrically connected to the source-drain layer.

7. The touch display panel according to claim 6, wherein the hole wall formed by the sidewall of the first insulating layer and the sidewall of the second insulating layer comprises an inclined surface portion, an included angle formed by the inclined surface portion and a horizontal plane ranges from 30 degrees to 80 degrees, and the second metal layer covers the inclined surface portion.

8. The touch display panel according to claim 1, wherein the source-drain layer comprises a first portion located in the display region and a second portion located in the peripheral region, and a thickness of the first portion is equal to a thickness of the second portion.

9. The touch display panel according to claim 1, wherein a thickness of the second metal layer is greater than a thickness of the first metal layer.

10. The touch display panel according to claim 1, wherein the first metal layer comprises a first touch electrode and a second touch electrode, the first touch electrode extends along a first direction, the second touch electrode extends along a second direction, and the first direction and the second direction are perpendicular to each other; and
wherein the first touch electrode and the second touch electrode are both located in the first insulating layer and located in the display region.

11. The touch display panel according to claim 1, wherein the source-drain layer comprises a first source-drain layer and a second source-drain layer, the second source-drain layer is disposed on the first source-drain layer, and the second source-drain layer is electrically connected to the first source-drain layer.

12. The touch display panel according to claim 11, wherein the peripheral region is provided with a solder pad, the solder pad comprises a first metal pad located in the first source-drain layer and a second metal pad located in the second source-drain layer, and the second metal pad is disposed on the first metal pad; and
wherein the second metal pad is in direct contact with and electrically connected to the first metal pad, and the first insulating layer exposes a top surface of the second metal pad.

13. The touch display panel according to claim 1, wherein the touch display panel further comprises a light-shielding member and a color filter layer; and
wherein in the display region, the light-shielding member covers the second metal layer, and the color filter layer is disposed on the light-shielding member and the second insulating layer.

14. The touch display panel according to claim 1, wherein a tensile elongation at break of the second insulating layer is greater than a tensile elongation at break of the first insulating layer.

15. A touch display device, comprising:
a touch display panel; and
a driving chip electrically connected to the touch display panel;
wherein the touch display panel comprising:
a thin-film transistor array substrate comprising a source-drain layer; and
a touch device comprising:
a first insulating layer, wherein the first insulating layer is an inorganic insulating layer;
a first metal layer disposed on the first insulating layer;
a second insulating layer disposed on the first insulating layer and the first metal layer, wherein the second insulating layer is an organic insulating layer; and
a second metal layer disposed on the second insulating layer;
wherein the touch display panel comprises a display region and a peripheral region located on at least one side of the display region, the peripheral region is provided with a wire-switching hole, the wire-switching hole at least penetrates through the first insulating layer and the second insulating layer, and the second metal layer is electrically connected to the source-drain layer through the wire-switching hole.

16. The touch display device according to claim 15, wherein the thin-film transistor array substrate further comprises a planarization layer disposed on the source-drain layer, and the wire-switching hole comprises a first opening penetrating through the planarization layer; and
wherein in the peripheral region, the first insulating layer is disposed on the planarization layer, a portion of the first insulating layer is disposed on the source-drain layer and located within the first opening, and at least a portion of the second insulating layer is disposed on the portion of the first insulating layer located within the first opening.

17. The touch display device according to claim 16, wherein the wire-switching hole further comprises a second opening penetrating through the first insulating layer and a third opening penetrating through the second insulating layer; and
wherein in a top view of the touch display panel, a diameter of a minimum circumscribed circle of the second opening and a diameter of a minimum circumscribed circle of the third opening are both smaller than a diameter of a minimum circumscribed circle of the first opening.

18. The touch display device according to claim 17, wherein in the top view of the touch display panel, the diameter of the minimum circumscribed circle of the second opening is smaller than the diameter of the minimum circumscribed circle of the third opening.

19. The touch display device according to claim 18, wherein a step portion is formed by an edge of the first insulating layer at the wire-switching hole and an edge of the second insulating layer at the wire-switching hole, and the second metal layer crosses through the step portion and is electrically connected to the source-drain layer.

20. The touch display device according to claim 17, wherein at the wire-switching hole, a sidewall of the first insulating layer is aligned with a sidewall of the second insulating layer; and wherein along a hole wall formed by the sidewall of the first insulating layer and the sidewall of the second insulating layer, the second metal layer extends from a top surface of the second insulating layer to a bottom of the wire-switching hole and is electrically connected to the source-drain layer.
